(19) United States
(12) Patent Application Publication
(10) Pub. No.: US 2024/0032257 A1
(43) Pub. Date: Jan. 25, 2024

(54) INTER-STAGE AIR-TO-LIQUID RADIATOR

(71) Applicant: Dell Products L.P., Round Rock, TX (US)

(72) Inventors: Richard M. EILAND, Austin, TX (US); Ashish SHRIVASTAVA, Bangalore (IN); Evangelos KOUTSAVDIS, Leander, TX (US)

(73) Assignee: Dell Products L.P., Round Rock, TX (US)

(21) Appl. No.: 17/871,684

(22) Filed: Jul. 22, 2022

(51) Int. Cl. H05K 7/20

(52) U.S. Cl. CPC H05K 7/20609; H05K 7/20209

(57) ABSTRACT

An information handling system may include a chassis configured to house a plurality of information handling resources, one or more air movers internal to the chassis and arranged to drive airflow proximate to the plurality of information handling systems, and an air-to-liquid radiator internal to the chassis and arranged such that the airflow flows proximate to the air-to-liquid radiator to cool airflow internal to the chassis prior to flowing proximate to at least one of the information handling resources.

### TECHNICAL FIELD

The present disclosure relates in general to information handling systems, and more particularly to providing inter-stage air-to-liquid radiators within liquid-cooled information handling systems.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

To control temperature of components of an information handling system, an air mover may direct air over one or more heatsinks thermally coupled to individual components. Traditional approaches to cooling components may include a “passive” cooling system that serves to reject heat of a component to air driven by one or more system-level air movers (e.g., fans) for cooling multiple components of an information handling system in addition to the peripheral component. Another traditional approach may include an “active” cooling system that uses liquid cooling, in which a heat-exchanging cold plate is thermally coupled to the component, and a chilled fluid is passed through conduits internal to the cold plate to remove heat from the component.

Typically, information handling system servers move airflow from air movers in a front to back manner. Airflow is heated as it flows thru an information handling system over high-powered components. Due to preheating of air from other upstream components, components in the rear of an information handling system must be designed for higher local ambient temperatures. However, increasing power levels of components such as processors and memories are creating more significant challenges for downstream components. Such increased preheating by upstream components may lead to higher required air mover speeds to minimize preheating from upstream components, but such a solution may lead to undesirable additional fan power consumption, negative acoustics, and disturbances to rotational drives. In addition, such increased preheating may lead to restricted feature support for downstream components if downstream component thermal health cannot be maintained. Further, such increased preheating may lead to localized hot spots created downstream of processors that further limit/restrict downstream component placement.

### SUMMARY

In accordance with the teachings of the present disclosure, the disadvantages and problems associated with existing approaches for thermal control in an information handling system may be substantially reduced or eliminated.

In accordance with embodiments of the present disclosure, an information handling system may include a chassis configured to house a plurality of information handling resources, one or more air movers internal to the chassis and arranged to drive airflow proximate to the plurality of information handling systems, and an air-to-liquid radiator internal to the chassis and arranged such that the airflow flows proximate to the air-to-liquid radiator to cool airflow internal to the chassis prior to flowing proximate to at least one of the information handling resources.

In accordance with these and other embodiments of the present disclosure, a method may include housing a plurality of information handling resources within a chassis of an information handling system, housing one or more air movers internal to the chassis and arranged to drive airflow proximate to the plurality of information handling systems, and housing an air-to-liquid radiator internal to the chassis and arranged such that the airflow flows proximate to the air-to-liquid radiator to cool airflow internal to the chassis prior to flowing proximate to at least one of the information handling resources.

In accordance with these and other embodiments of the present disclosure, a method may include driving, with one or more air movers internal to a chassis configured to house a plurality of information handling resources, airflow proximate to the plurality of information handling systems. The method may also include cooling airflow prior to the airflow flowing proximate to at least one of the plurality of information handling resources with an air-to-liquid radiator internal to the chassis and arranged such that the airflow flows proximate to the air-to-liquid radiator to cool airflow internal to the chassis.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, the block diagram representing a top plan view of the example information handling system, in accordance with embodiments of the present disclosure;

FIG. 2 illustrates a block diagram of selected components of another example information handling system, the block diagram representing a top plan view of the example information handling system, in accordance with embodiments of the present disclosure;

FIG. 3 illustrates a block diagram of selected components of yet another example information handling system, the block diagram representing a top plan view of the example information handling system, in accordance with embodiments of the present disclosure; and

FIG. 4 illustrates a block diagram of selected components of yet another example information handling system, the block diagram representing a top plan view of the example information handling system, in accordance with embodiments of the present disclosure.

### DETAILED DESCRIPTION

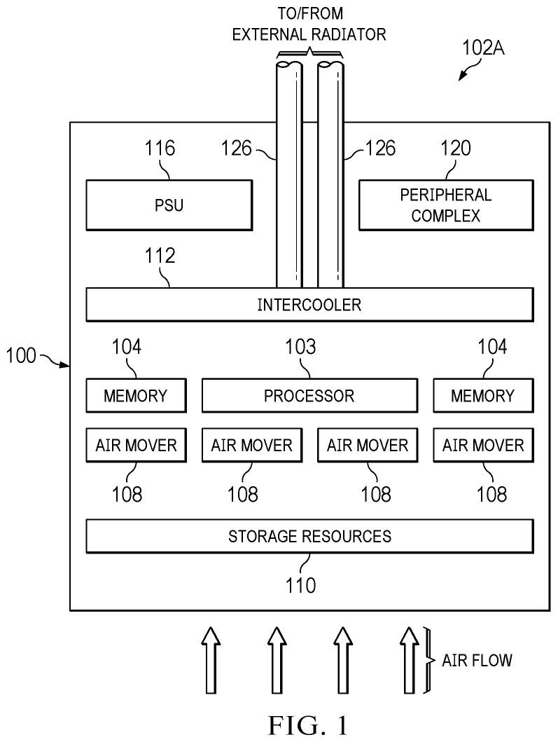

Preferred embodiments and their advantages are best understood by reference to FIGS. 1 through 4, wherein like numbers are used to indicate like and corresponding parts. For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of selected components of an example information handling system 102A, the block diagram representing a top plan view of the example information handling system, in accordance with embodiments of the present disclosure. In some embodiments, information handling system 102A may comprise a server chassis configured to house a plurality of servers or “blades.” In other embodiments, information handling system 102A may comprise a personal computer (e.g., a desktop computer, laptop computer, mobile computer, and/or notebook computer). In yet other embodiments, information handling system 102A may comprise a storage enclosure configured to house a plurality of physical disk drives and/or other computer-readable media for storing data. As shown in FIG. 1, information handling system 102A may include a chassis 100 housing a processor 103, memory 104, one or more air movers 108, storage resources 110, an intercooler 112, a power supply unit (PSU) 116, a peripheral complex 120, and fluidic conduits 126.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102A.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102A is turned off.

An air mover 108 may include any mechanical or electro-mechanical system, apparatus, or device operable to move air and/or other gases in order to cool information handling resources of information handling system 102A. In some embodiments, system air mover 108 may comprise a fan (e.g., a rotating arrangement of vanes or blades which act on the air). In other embodiments, an air mover 108 may comprise a blower (e.g., a centrifugal fan that employs rotating impellers to accelerate air received at its intake and change the direction of the airflow). In these and other embodiments, rotating and other moving components of system air mover 108 may be driven by a motor. The rotational speed of the motor may be controlled by an air mover control signal communicated from a thermal control system. In operation, system air mover 108 may cool information handling resources of information handling system 102A by drawing cool air into chassis 100 housing the information handling resources from outside chassis 100, expel warm air from inside chassis 100 to the outside of chassis 100, and/or move air across one or more heat sinks (not explicitly shown) internal to chassis 100 to cool one or more information handling resources.

Storage resources 110 may include one or more hard disk drives, magnetic tape libraries, optical disk drives, magneto-optical disk drives, compact disk drives, compact disk arrays, disk array controllers, and/or any other system, apparatus or device operable to store media. In some embodiments, storages resource 110 may comprise a plurality of physical storage resources that may appear to an operating system or virtual machine executing on information handling system 102A as a single logical storage unit or virtual storage resource. For example, each such virtual storage resource may comprise a RAID. Thus, in some embodiments, a virtual storage resource may comprise a redundant array of physical storage resources. In the same or alternative embodiments, a virtual storage resource may be implemented using a RAID standard. Although FIG. 1 depicts storage resources 110 internal to information handling system 102A, in some embodiments, storage resource 110 may be external to information handling system 102A (e.g., embodied by a physical array of external hard disk drives).

Intercooler 112 may include any device, system or apparatus configured to transfer thermal energy from one medium (e.g., air within chassis 100) to another (e.g., coolant fluid flowing through intercooler 112) for the purpose of cooling and heating. For example, intercooler 112 may comprise an air-to-liquid radiator in which thermal energy is transferred from air flowing proximate to intercooler 112 to coolant fluid flowing through intercooler 112, in order to cool the air flowing proximate to intercooler 112. In some embodiments, intercooler 112 may include fluidic channels and/or conduits in at least a portion of intercooler 112. Such fluidic channels and/or conduits may be fluidically coupled to one or more of fluidic conduits 126 (which may enter or exit through any of the front, rear, sides, top, or bottom of chassis 100 as is suitable) and an external cooling system which may include suitable components for cooling the coolant fluid, including without limitation a liquid-to-air radiator, liquid-to-liquid radiator, cooling distribution unit, and/or building/facility chilled water.

PSU 116 may comprise any suitable system, device, or apparatus for delivering electrical energy to electrical and electronic components of information handling system 102A in order to enable such components to carry out their respective functionality. Thus, PSU 116 may comprise one or more of an alternating current-to-direct current (AC/DC) power converter, direct current-to-direct current (DC/DC) power converter, battery, or any other suitable device.

Peripheral complex 120 may comprise one or more other information handling resources, including without limitation co-processors, graphics processors, buses, memories, I/O devices and/or interfaces, storage resources, network interfaces, motherboards, integrated circuit packages, electro-mechanical devices, displays, and/or other devices. Fluidic conduits 126 may be coupled between intercooler 112 and an external cooling system including an external heat rejection system for cooling coolant fluid flowing from intercooler 112 to the external heat rejection system. Fluidic conduits 126 may include any suitable system, device, or apparatus for conveying fluid from one location to another (e.g., a pipe, tube, hose, etc.), and may be constructed from metal, plastic, rubber, and/or other suitable material.

In addition to processor 103, memory 104, one or more air movers 108, storage resources 110, an intercooler 112, a power supply unit (PSU) 116, a peripheral complex 120, and fluidic conduits 126, information handling system 102A may include one or more other information handling resources.

In operation, air movers 108 shown in FIG. 1 may cause air to be drawn in from a “front” of information handling system 102A (e.g., the bottom edge of chassis 100 as shown in FIG. 1), with air flowing proximate to storage resources 110, through air movers 108, such that air movers 108 may further drive airflow proximate to processor 103, memory 104, intercooler 112, PSU 116, and peripheral complex 120. As airflow passes proximate to intercooler 112, heat present in such air may be transferred from the air to coolant liquid flowing in intercooler 112, thus cooling the air prior to such air flowing proximate to PSU 116 and peripheral complex 120. Thus, intercooler 112 may cool air at an intermediate location within chassis 100, thus providing a cooler local ambient/inlet air temperature to components downstream of intercooler 112 than would be the case in the absence of intercooler 112.

Further, chilled coolant fluid may be conveyed to intercooler 112 from an external heat rejection system via a fluidic conduit 126 and such coolant fluid may be conveyed, after receiving heat transferred from airflow proximate to intercooler 112, via a fluidic conduit 126 to the external heat rejection system, where such coolant fluid may be again chilled prior to recirculation to intercooler 112.

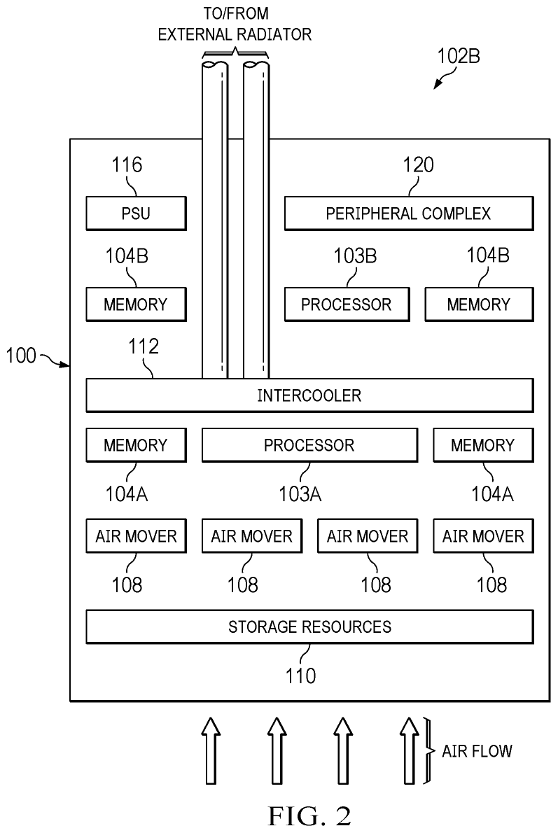

Although for clarity and exposition, FIG. 1 depicts a particular example arrangement and configuration of information handling resources, it is understood that an intercooler 112 may be provided to provide internal air-to-liquid cooling of airflow internal to a chassis in any suitable arrangement and configuration of an information handling system. For example, FIG. 2 illustrates a block diagram of selected components of an example information handling system 102B, the block diagram representing a top plan view of example information handling system 102B, in accordance with embodiments of the present disclosure. Information handling system 102B depicted in FIG. 2 is similar in many respects to information handling system 102A depicted in FIG. 1. Accordingly, only certain differences between information handling system 102A and information handling system 102B are described below.

One main difference between information handling system 102A and information handling system 102B is that information handling system 102B includes a “shadowed” processor layout, including processor 103A and memory 104A upstream of intercooler 112 and processor 103B and memory 104B downstream of intercooler 112. Thus, in the arrangement and configuration shown in FIG. 2, intercooler 112 may serve to remove heat of airflow from processor 103A and memory 104A, thus lowering the temperature of the local ambient/inlet air temperature to processor 103B and memory 104B, potentially lowering such temperature to the approximate local ambient/inlet air temperature to processor 103A and memory 104A.

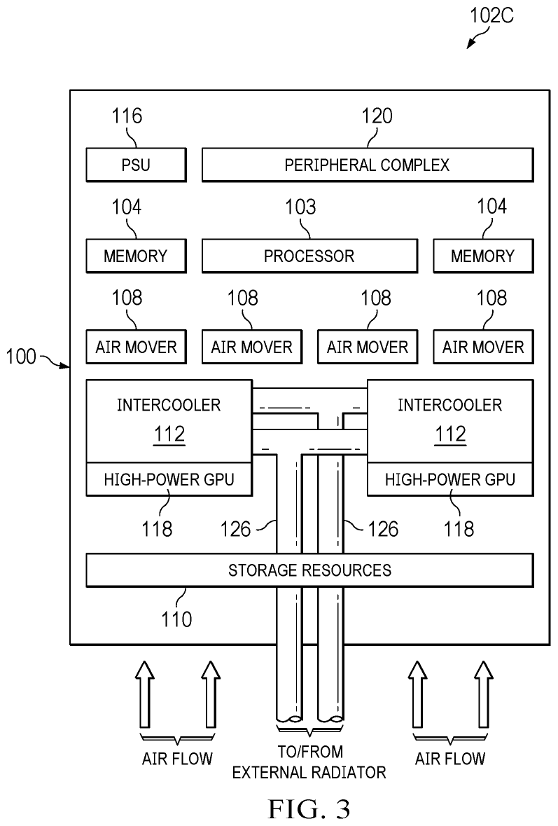

As another example, FIG. 3 illustrates a block diagram of selected components of an example information handling system 102C, the block diagram representing a top plan view of example information handling system 102C, in accordance with embodiments of the present disclosure. Information handling system 102C depicted in FIG. 3 is similar in many respects to information handling system 102A depicted in FIG. 1. Accordingly, only certain differences between information handling system 102A and information handling system 102C are described below.

One main difference between information handling system 102A and information handling system 102C is that one or more high-power graphics processing units (GPUs) 118 may be located upstream of air movers 108. Further, information handling system 102C may include one or more intercoolers 112 directly attached to, or in the immediate proximity of, a respective high-powered component, such as a high-powered GPU 118. Thus, in information handling system 102C, intercoolers 112 may in a sense be dedicated to components known to or suspected to generate large quantities of heat.

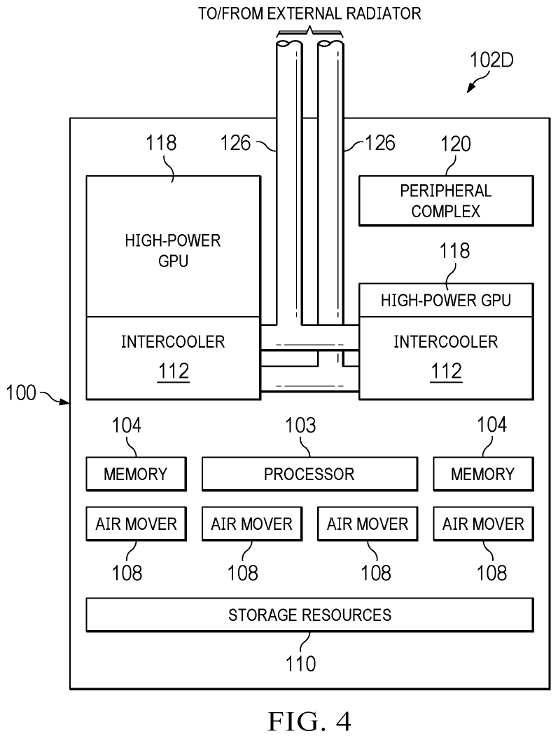

As another example, FIG. 4 illustrates a block diagram of selected components of an example information handling system 102D, the block diagram representing a top plan view of example information handling system 102D, in accordance with embodiments of the present disclosure. Information handling system 102D depicted in FIG. 4 is similar in many respects to information handling system 102C depicted in FIG. 3. Accordingly, only certain differences between information handling system 102C and information handling system 102D are described below.

One main difference between information handling system 102C and information handling system 102D is that rather than being located upstream of processor 103 and memory 104 as in information handling system 102C, in information handling system 102D, high-power GPUs 118 may be located downstream of processor 103 and memory 104, and thus intercoolers 112 directly attached to, or in the immediate proximity of, high-powered GPUs 118, to allow for pre-cooling of air to meet thermal requirements for the local ambient/inlet temperatures of air to high-powered GPUs 118.

Advantageously, the systems and methods herein may allow for favorable thermal properties of liquid cooling without direct attachments of liquid cooling devices (e.g., cold plates) to electrical components. Further, these systems and methods may allow for removal of an internal component's exhaust heat from other internal components while still using an external liquid cooling supply. In addition, use of intercoolers 112 may allow for more uniform temperature to downstream components because hot spots from specific high-power components may be reduced or eliminated. In addition, air movers may run at lower speeds as compared to traditional approaches because a larger temperature difference may be permitted across the heat-generating components.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
a chassis configured to house a plurality of information handling resources;
one or more air movers internal to the chassis and arranged to drive airflow proximate to the plurality of information handling systems; and
an air-to-liquid radiator internal to the chassis and arranged such that the airflow flows proximate to the air-to-liquid radiator to cool airflow internal to the chassis prior to flowing proximate to at least one of the information handling resources.

2. The information handling system of claim 1, wherein the air-to-liquid radiator is configured to fluidically couple to a heat rejection system external to the chassis.

3. The information handling system of claim 1, wherein the air-to-liquid radiator is located, with respect to direction of the airflow, downstream of at least a first information handling resource of the plurality of information handling resources and upstream of at least a second information handling resource of the plurality of information handling resources.

4. The information handling system of claim 1, wherein the air-to-liquid radiator is located, with respect to direction of the airflow, downstream of at least a first processor of the plurality of information handling resources and upstream of at least a second processor of the plurality of information handling resources.

5. The information handling system of claim 1, wherein the air-to-liquid radiator is directly attached to, or in the immediate proximity of, an information handling resource of the plurality of information handling resources and is downstream of the information handling resource such that the air-to-liquid radiator cools airflow heated by the information handling resource.

6. The information handling system of claim 1, wherein the air-to-liquid radiator is directly attached to, or in the immediate proximity of, an information handling resource of the plurality of information handling resources and is upstream of the information handling resource such that the air-to-liquid radiator pre-cools airflow received by the information handling resource.

7. A method comprising:
housing a plurality of information handling resources within a chassis of an information handling system;
housing one or more air movers internal to the chassis and arranged to drive airflow proximate to the plurality of information handling systems; and
housing an air-to-liquid radiator internal to the chassis and arranged such that the airflow flows proximate to the air-to-liquid radiator to cool airflow internal to the chassis prior to flowing proximate to at least one of the information handling resources.

8. The method of claim 7, further comprising fluidically coupling the air-to-liquid radiator to a heat rejection system external to the chassis.

9. The method of claim 7, further comprising locating the air-to-liquid radiator, with respect to direction of the airflow, downstream of at least a first information handling resource of the plurality of information handling resources and upstream of at least a second information handling resource of the plurality of information handling resources.

10. The method of claim 7, further comprising locating the air-to-liquid radiator, with respect to direction of the airflow, downstream of at least a first processor of the plurality of information handling resources and upstream of at least a second processor of the plurality of information handling resources.

11. The method of claim 7, further comprising arranging the air-to-liquid radiator directly attached to, or in the immediate proximity of, an information handling resource of the plurality of information handling resources and downstream of the information handling resource such that the air-to-liquid radiator cools airflow heated by the information handling resource.

12. The method of claim 7, further comprising arranging the air-to-liquid radiator directly attached to, or in the immediate proximity of, an information handling resource of the plurality of information handling resources and upstream of the information handling resource such that the air-to-liquid radiator pre-cools airflow received by the information handling resource.

13. A method comprising:
driving, with one or more air movers internal to a chassis configured to house a plurality of information handling resources, airflow proximate to the plurality of information handling systems; and
cooling airflow prior to the airflow flowing proximate to at least one of the plurality of information handling resources with an air-to-liquid radiator internal to the chassis and arranged such that the airflow flows proximate to the air-to-liquid radiator to cool airflow internal to the chassis.

14. The method of claim 13, wherein the air-to-liquid radiator is configured to fluidically couple to a heat rejection system external to the chassis.

15. The method of claim 13, wherein the air-to-liquid radiator is located, with respect to direction of the airflow, downstream of at least a first information handling resource of the plurality of information handling resources and upstream of at least a second information handling resource of the plurality of information handling resources.

16. The method of claim 13, wherein the air-to-liquid radiator is located, with respect to direction of the airflow, downstream of at least a first processor of the plurality of information handling resources and upstream of at least a second processor of the plurality of information handling resources.

17. The method of claim 13, further comprising cooling airflow heated by an information handling resource of the plurality of information handling resources with the air-to-liquid radiator wherein the air-to-liquid radiator is directly attached to, or in the immediate proximity of, and is downstream of the information handling resource.

18. The method of claim 13, further comprising pre-cooling airflow received by an information handling resource of the plurality of information handling resources with the air-to-liquid radiator wherein the air-to-liquid radiator is directly attached to, or in the immediate proximity of, and is upstream of the information handling resource.
